(19) United States
(12) Patent Application Publication
(10) Pub. No.: US 2015/0371698 A1
(43) Pub. Date: Dec. 24, 2015

(54) PRINTED CIRCUIT BOARD, AND PRINTED WIRING BOARD

(71) Applicant: CANON KABUSHIKI KAISHA, Tokyo (JP)

(72) Inventor: Hiroyuki Mizuno, Yokohama-shi (JP)

(21) Appl. No.: 14/736,003

(22) Filed: Jun. 10, 2015

(30) Foreign Application Priority Data
Jun. 18, 2014 (JP) 2014-124973

(51) Int. Cl. G11C 11/401

(52) U.S. Cl. CPC G11C 11/401

(57) ABSTRACT

A motherboard includes a main wiring as a transmission line for a signal transmitted by a memory controller, and a branching wiring branched from a branching point of the main wiring and connected to the memory device. Furthermore, the motherboard includes a branching wiring including a land to which a memory device may be joined and branched from a branching point, and an open stub formed extending from the land. According to such a structure, ringing in the waveform of a signal received by the receiving circuit may be suppressed at the time of both single-side mounting and double-side mounting, and also, ringing of a signal may be sufficiently suppressed in the case where the number of DIMMs used by the same substrate is changed.

### BACKGROUND OF THE INVENTION

1. Field of the Invention

The present invention relates to a printed circuit board including a receiving circuit that is electrically connected to a branching wiring branched from a main wiring, and a printed wiring board on which the main wiring and the branching wiring are formed.

2. Description of the Related Art

Generally, a memory system includes a memory controller and a plurality of memory devices. As the memory device, a DDR3-SDRAM (Double Data Rate 3 Synchronous Dynamic Random Access Memory) is generally known.

As the mode of mounting the memory device, there are a case of mounting on a motherboard, and a case of mounting on a module substrate. In the case where the memory device is mounted on a module substrate, a module substrate on which the memory device is mounted is connected by a connector to the motherboard.

The memory controller transmits an address signal or a command signal (address/command signal), and each memory device is controlled by receiving the address/command signal, and transmission/reception of a data signal is performed between the memory controller and the plurality of memory devices. A particularly sophisticated electronic appliance often has a plurality of DDR3-SDRAMs installed to secure memory capacity.

A memory device which is a DDR3-SDRAM includes a function of adjusting the signal transmission timing. Each memory device is connected to a unicursal main wiring called a fly-by capable of increasing the speed of the address/command signal (see JEDEC standard No. 21C PC3-6400/PC3-8500/PC3-10600/PC3-12800/PC3-14900/PC3-17000 DDR3 Unbuffered SO-DIMM Reference Design Specification Revision 2.0).

In JEDEC standard No. 21C PC3-6400/PC3-8500/PC3-10600/PC3-12800/PC3-14900/PC3-17000 DDR3 Unbuffered SO-DIMM Reference Design Specification Revision 2.0, a specification for mounting eight memories based on double-side memory mounting, and a specification for mounting four memories based on single-side memory mounting are set as different standards.

Also, in JEDEC standard No. 21C PC3-6400/PC3-8500/PC3-10600/PC3-12800/PC3-14900/PC3-17000 DDR3 Unbuffered SO-DIMM Reference Design Specification Revision 2.0, a BGA (Ball grid array) semiconductor package is used for the memory device. On a printed wiring board, a via that forms a branching wiring branched from a main wiring to the memory device and that is formed on the main wiring, a land that is connected to a receiving terminal of the BGA semiconductor package, and a lead-out wiring that connects the via and the land are formed. By using a small-diameter via that can be arranged between lands at a part of the branching wiring, the length of the branching wiring to the memory device may be reduced.

However, according to the structure of JEDEC standard No. 21C PC3-6400/PC3-8500/PC3-10600/PC3-12800/PC3-14900/PC3-17000 DDR3 Unbuffered SO-DIMM Reference Design Specification Revision 2.0, a short wiring length of about 1.6 to 5 mm is defined for the branching wiring according to DIMM specifications. Thus, conventionally, the via is arranged next to the lands to reduce the wiring length of the lead-out wiring, and the wiring length of the branching wiring is thereby reduced. However, in the case where the number of bus wirings is large, as in the case of address/command wirings, and where the lands are densely arranged, the via cannot be arranged between the lands, and is sometimes arranged on the outside of the land group, and in such a case, the wiring length of the branching wiring is increased. Longer wiring length of the branching wiring leads to greater problems of signal attenuation and reflection, thus leads to disturbance in the signal waveform, that is, occurrence of signal ringing. What is particularly regarded as a problem with respect to the waveform of the address/command signal at the DDR3-SDRAM is an increase in the signal ringing which then results in a case where the input voltage condition of a signal is not satisfied.

Moreover, in JEDEC standard No. 21C PC3-6400/PC3-8500/PC3-10600/PC3-12800/PC3-14900/PC3-17000 DDR3 Unbuffered SO-DIMM Reference Design Specification Revision 2.0, a topology specification for mounting eight memories based on double-side mounting where the memory devices are mounted on both sides of a substrate, and a topology specification for mounting four memories based on single-side mounting where the memory devices are mounted on only one side of a substrate are set as different standards. That is, a case of using a substrate of the double-side mounting topology for single-side mounting is not defined. In the case where the substrate of double-side mounting topology is used in the state of single-side mounting as it is, the mounting state is different for the front side and the back side, and thus signal ringing is further increased, and a case where the input voltage condition of a signal is not satisfied is more likely to occur. Moreover, signal ringing is not sufficiently suppressed also in a case of changing the number of DIMMs to be used by the same substrate, in addition to a case of using a substrate of double-side mounting topology for single-side mounting.

Accordingly, the present invention provides a printed circuit board and a printed wiring board where the ringing of a signal received by a receiving circuit is suppressed in both the double-side mounting state and the single-side mounting state, or in the case of changing the number of DIMMs used by the same substrate.

### SUMMARY OF THE INVENTION

According to an aspect of the present invention, a printed circuit board comprises: a printed wiring board having a mount surface on which a transmission line is formed; a transmitting circuit mounted on the mount surface; a first receiving circuit mounted on the mount surface, and receiving a signal transmitted from the transmitting circuit through the transmission line formed on the printed wiring board; and a second receiving circuit mounted on the mount surface, and receiving a signal transmitted from the transmitting circuit through the transmission line formed on the printed wiring board, wherein the transmission line comprises: a main wiring configured to transmit the signal from the transmitting circuit; a first branching wiring branched from a first branching point of the main wiring, and connected to the first receiving circuit; a second branching wiring branched from the first branching point, and connected to the second receiving circuit; and an open stub branched from the second branching wiring.

Further features of the present invention will become apparent from the following description of exemplary embodiments with reference to the attached drawings.

### BRIEF DESCRIPTION OF THE DRAWINGS

FIG. 1 is a topology diagram illustrating a wiring structure of a memory system of a double-side mounting structure according to a first embodiment of the present invention.

FIG. 2 is a cross-sectional diagram of the memory system of a double-side mounting structure according to the first embodiment of the present invention.

FIG. 3 is a plan diagram of the other mount surface of a motherboard according to the first embodiment of the present invention, around the mounted area of a memory device.

FIG. 4 is an explanatory diagram illustrating a schematic structure of a memory system of a single-side mounting structure according to the first embodiment of the present invention.

FIGS. 5A, 5B and 5C are diagrams for describing reflection and transmission of a signal component at a branching point according to the first embodiment of the present invention.

FIGS. 6A, 6B and 6C are diagrams for describing a received waveform of a memory device where memory devices are mounted on both sides of a motherboard for double-side mounting according to a comparative example.

FIGS. 7A, 7B and 7C are diagrams for describing a received waveform of a memory device where memory devices are mounted on one side of the motherboard for double-side mounting according to the comparative example.

FIGS. 8A, 8B and 8C are diagrams for describing a received waveform of a memory device where memory devices are mounted on one side of the motherboard according to the first embodiment of the present invention.

FIGS. 9A, 9B and 9C are diagrams for describing a received waveform of a memory device where memory devices are mounted on both sides of the motherboard according to the first embodiment of the present invention.

FIGS. 10A, 10B, 10C and 10D are waveform diagrams illustrating results of performing simulation on the memory system according to the first embodiment of the present invention in a single-side mounting state and in a double-side mounting state, and a memory system according to the comparative example in a single-side mounting state and in a double-side mounting state.

FIG. 11 is a graph illustrating, with respect to the memory system according to the first embodiment of the present invention, a difference of a minimum voltage of ringing to a determination reference voltage in a case where the electric length of an open stub is changed.

FIG. 12 is a topology diagram illustrating a wiring structure of a memory system according to a second embodiment of the present invention.

FIGS. 13A, 13B, 13C and 13D are waveform diagrams illustrating results of performing simulation on the memory system according to the second embodiment of the present invention in a single-side mounting state and in a double-side mounting state, and a memory system according to a comparative example in a single-side mounting state and in a double-side mounting state.

FIG. 14 is a topology diagram illustrating a wiring structure of an example modification of the memory system according to the second embodiment of the present invention.

### DESCRIPTION OF THE EMBODIMENTS

Preferred embodiments of the present invention will now be described in detail in accordance with the accompanying drawings.

### First Embodiment

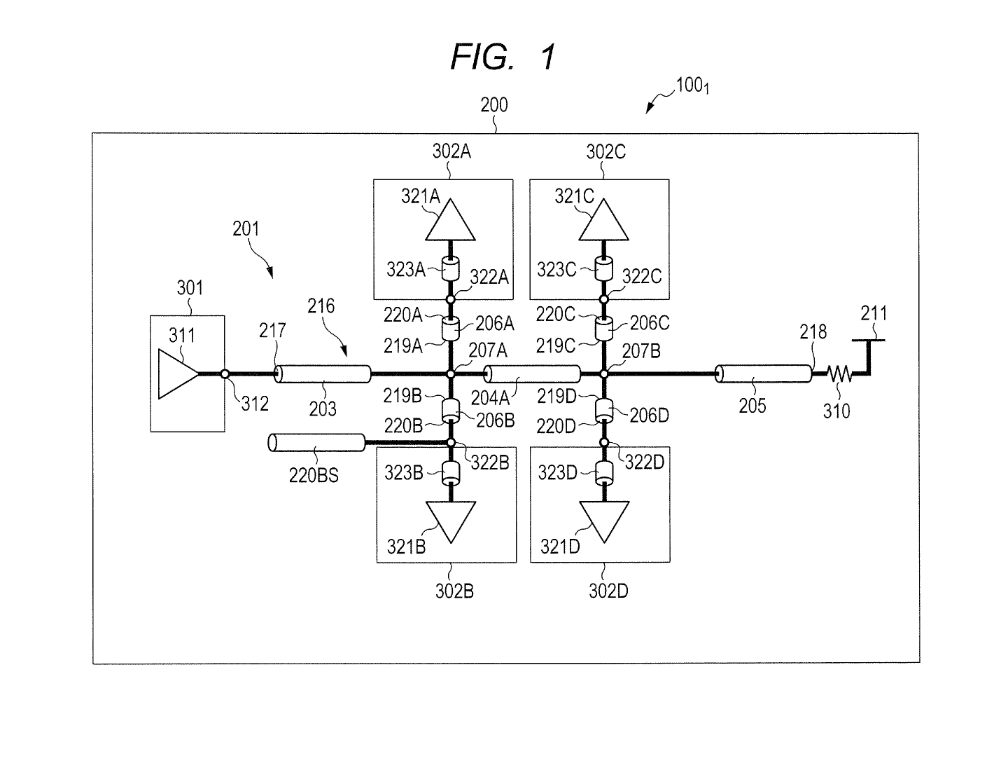

FIG. 1 is a topology diagram illustrating a wiring structure of a memory system as an example of a printed circuit board according to a first embodiment of the present invention. A memory system 100₁ which is a printed circuit board includes a motherboard 200 which is a printed wiring board, a memory controller 301 which is a transmitting circuit, and a plurality of memory devices 302A to 302D which are a plurality of receiving circuits. In the first embodiment, the memory devices 302A to 302D are DDR3-SDRAMs (Double Data Rate 3 Synchronous Dynamic Random Access Memory). The memory controller 301 and the plurality of memory devices 302A to 302D are mounted on the motherboard 200. FIG. 1 illustrates a double-side mounting structure where the memory devices are mounted on both sides of the motherboard 200.

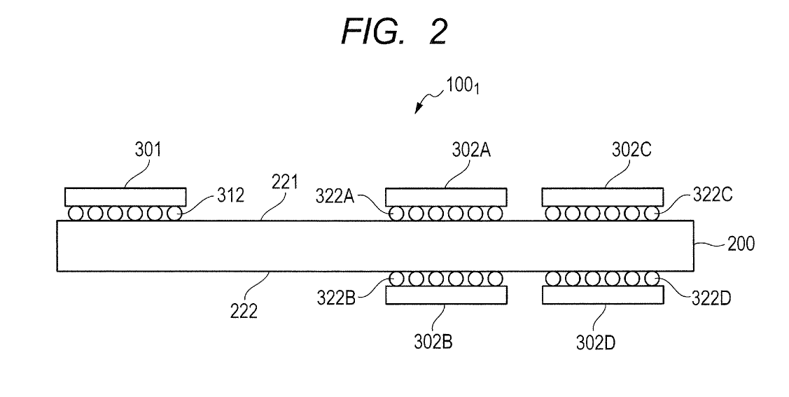

FIG. 2 is a cross-sectional diagram of the memory system 100₁ of the double-side mounting structure. The motherboard 200 has a pair of mount surfaces 221 and 222 (a front surface 221 and a back surface 222) where the memory devices can be mounted. Additionally, in the first embodiment, the memory controller 301 may be mounted on one of the pair of mount surfaces 221 and 222 (in FIG. 2, the mount surface 221). The memory controller 301 and the memory devices 302A to 302D are BGA (Ball grid array) semiconductor packages.

The memory controller 301 is mounted on one of the pair of mount surfaces 221 and 222 of the motherboard 200 (in FIG. 2, the mount surface 221). The memory devices 302A and 302C are first receiving circuits mounted on one mount surface 221 of the pair of mount surfaces 221 and 222. In the first embodiment, a plurality (two) of first receiving circuits are mounted on the mount surface 221. The memory device 302B is a second receiving circuit, different from the first receiving circuit, mounted on the other mount surface 222 of the pair of mount surfaces 221 and 222. Moreover, the memory device 302D is a third receiving circuit mounted on the mount surface 222, different from the first and the second receiving circuits.

Additionally, the mode of the present invention is not limited to a mode where the memory devices 302A and 302C are mounted on one mount surface 221, and where the memory devices 302B and 302D are mounted on the other mount surface 222. The memory devices 302A, 302B, 302C and 302D may be mounted on the same mount surface. In this case, the memory devices are desirably mounted vertically to the substrate so that the mount surface area of the memory devices does not become great, and the length of the branching wiring from a main wiring 216 described later is not increased.

Now, the front surface and the back surface of the motherboard 200, which are the mount surfaces, are used in a relative sense, and the front surface may also be referred to as one surface or a first surface, and the back surface on the opposite side from the front surface may also be referred to as the other surface or a second surface. Also, the front surface of the motherboard 200 may also be referred to as a front layer (a first layer), and the back surface as a back layer (a second layer). An inner layer (a conductive layer) is arranged between the surface layer (a conductive layer) and a back layer (a conductive layer) via insulating layers. A conductive layer is a layer where a conductor pattern is arranged. A conductor pattern is a member having conductivity, such as copper, for example.

The memory controller 301 is for controlling the memory devices 302A to 302D. The memory controller 301 transmits digital signals to the memory devices 302A to 302D, and in the first embodiment, transmits address signals or command signals (address/command signals) via the motherboard 200.

Each of the memory devices 302A to 302D receives an address/command signal transmitted from the memory controller 301 via the motherboard 200. Then, the memory controller 301 and each of the memory devices 302A to 302D perform transmission/reception of data signals via a bus line for data signals, not illustrated.

In the first embodiment, a bus line for address signals and a bus line for command signals have a wiring structure according to a fly-by method, and one of these plurality of bus lines is illustrated in FIG. 1.

The memory controller 301 is a semiconductor package including a transmitting element 311 formed from a semiconductor element, and a transmitting terminal 312 connected to the transmitting element 311.

The memory devices 302A to 302D are semiconductor packages respectively including memory cells 321A to 321D each being formed from a semiconductor element which is a receiving element, and receiving terminals 322A to 322D connected to the memory cells 321A to 321D via inner wirings 323A to 323D. The memory devices 302A to 302D are semiconductor packages having the same structure and the same property.

Additionally, the inner wirings 323A to 323D are effective inner wirings of the memory devices 302A to 302D. That is, depending on the lengths of package wirings and the capacitive components of the memory cells 321A to 321D, a propagation delay occurs, in the memory devices 302A to 302D, in the signals propagated from the receiving terminals 322A to 322D to the memory cells 321A to 321D. This propagation delay is translated into the length of a wiring pattern (the electric length) on the motherboard 200 and is given as the length of the effective inner wirings (the electric length) of the memory devices 302A to 302D, and these inner wirings are illustrated as the inner wirings 323A to 323D in FIG. 1.

The motherboard 200 includes a bus wiring 201 that connects the memory controller 301 and the memory devices 302A to 302D by a fly-by method.

The bus wiring 201 includes a main wiring 216 whose leading end 217 is electrically connected to the transmitting terminal 312 of the memory controller 301, and whose terminating end 218 is electrically connected to one end of a terminating end resistor (terminator) 310. The other end of the terminating end resistor 310 is electrically connected to a terminating end wiring 211 to which a terminating end potential is applied.

The main wiring 216 is formed extending in the wiring direction from the leading end 217 to the terminating end 218 in the shape of unicursal line. In this manner, the leading end 217 in the wiring direction of the main wiring 216 is directly electrically connected to the transmitting terminal 312 of the memory controller 301, and the terminating end 218 in the wiring direction of the main wiring 216 is electrically connected to the terminating end resistor 310. Thus, reflection of a signal at the terminating end 218 is suppressed by the terminating end resistor 310.

The bus wiring 201 includes a plurality of branching wirings (a first branching wiring 206A, a third branching wiring 206C) branched, respectively, from a plurality of branching points 207A (a first branching point) and 207B (a second branching point) at different positions on the main wiring 216. Of the plurality of branching points 207A and 207B, the branching point closest to the leading end 217 is the first branching point 207A. The bus wiring 201 also includes a branching wiring (a second branching wiring) 206B branched from the branching point 207A. The bus wiring 201 further includes a branching wiring (a fourth branching wiring) 206D branched from the branching point 207B, not the branching point 207A.

Memory devices may be connected to all the branching wirings 206A and 206C that are formed extending to one mount surface 221, and in the first embodiment, the memory devices 302A and 302C are connected.

Additionally, memory devices may be connected to the branching wirings 206B and 206D that are formed extending to the other mount surface 222, but the memory devices do not actually have to be connected. That is, memory devices do not have to be mounted on the other mount surface 222, and thus at least one of the memory devices 302B and 302D may be omitted. In the first embodiment, the memory devices 302B and 302D are connected to all the branching wirings 206B and 206D that are formed extending to the other mount surface 222.

That is, the memory device 302A is electrically connected to the branching wiring 206A, the memory device 302B to the branching wiring 206B, the memory device 302C to the branching wiring 206C, and the memory device 302D to the branching wiring 206D.

Specifically, one end 219A of the branching wiring 206A in the wiring direction and one end 219B of the branching wiring 206B in the wiring direction are electrically connected to the branching point 207A. Also, one end 219C of the branching wiring 206C in the wiring direction and one end 219D of the branching wiring 206D in the wiring direction are electrically connected to the branching point 207B. Also, other ends 220A to 220D of the branching wirings 206A to 206D in the wiring direction are electrically connected to the receiving terminals 322A to 322D of the memory devices 302A to 302D, respectively.

Additionally, FIG. 1 illustrates the one end 219A of the branching wiring 206A in the wiring direction and the one end 219B of the branching wiring 206B in the wiring direction at different positions from the branching point 207A, but the positions on the actual printed wiring board may be the same. Likewise, the one end 219C of the branching wiring 206C in the wiring direction and the one end 219D of the branching wiring 206D in the wiring direction are illustrated to be at different positions from the branching point 207B, but the positions on the actual printed wiring board may be the same.

The other ends 220A to 220D of the branching wirings 206A to 206D are formed by lands (hereinafter, the other end(s) will be referred to as “land(s)”). The receiving terminals 322A to 322D of the memory devices 302A to 302D are joined to the lands 220A to 220D, respectively, by solders or the like. That is, the lands 220A to 220D of the branching wirings 206A to 206D are formed in such a way as to allow joining of the receiving terminals 322A to 322D of the memory devices 302A to 302D.

Additionally, FIG. 1 illustrates the other end 220A of the branching wiring 206A and the receiving terminal 322A of the memory device 302A at different positions, but the positions on the actual printed wiring board may be the same position (the land 220A). The same thing can be said for the other ends 220B to 220D of the branching wirings 206B to 206D and the receiving terminals 322B to 322D of the memory devices 302B to 302D.

Here, the branching wiring 206A is the branching wiring extending to the front layer side (a front layer side branching wiring), and the branching wiring 206B is the branching wiring extending to the back layer side (a back layer side branching wiring). Also, the branching wiring 206C is the branching wiring extending to the front layer side (a front layer side branching wiring), and the branching wiring 206D is the branching wiring extending to the back layer side (a back layer side branching wiring). The branching wirings 206A to 206D have about the same length (the electric length).

The main wiring 216 includes a wiring 203 between the leading end 217 and the branching point 207A, and a wiring 204A between the branching point 207A and the branching point 207B. Also, the main wiring 216 includes a wiring 205 between the branching point 207B and the terminating end 218.

The main wiring 216 is formed on the inner layer or the front and back layers of the motherboard 200, and the branching wirings 206A and 206C are formed across the inner layer and the front layer of the motherboard 200. The branching wirings 206B and 206D are formed across the inner layer and the back layer of the motherboard 200.

An open stub 220BS is formed extending from the land 220B, of the branching wiring 206B, to which the receiving terminal 322B of the memory device 302B is joined. One end of the open stub 220BS in the wiring direction is electrically connected to the land 220B, and the other end of the open stub 220BS is an open end that is open. The open stub 220BS is formed on the mount surface 222 (FIG. 2).

The electric length of the open stub 220BS in the wiring direction is set to be substantially the same as the electric length of the inner wiring 323A.

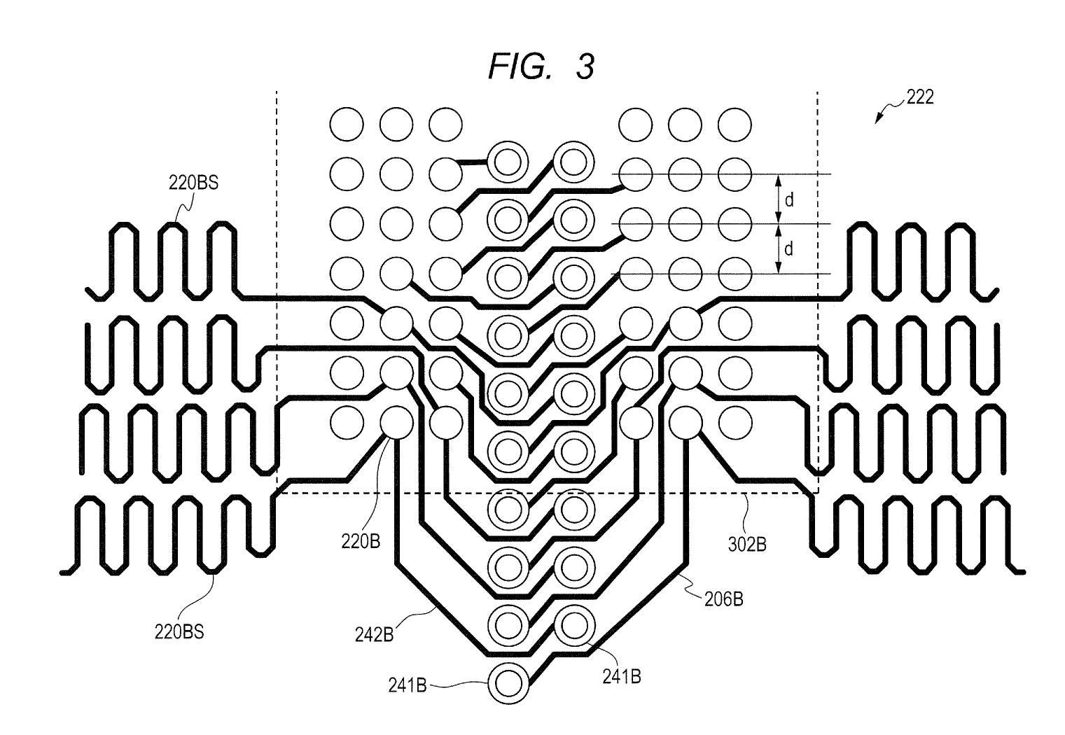

FIG. 3 is a plan diagram of the mount surface 222 of the motherboard 200, around the mounted area of the memory device 302B. In FIG. 3, a plurality of branching wirings 206B are illustrated, and are, respectively, electrically connected to a plurality of main wirings 216, not illustrated in FIG. 2, formed on the inner layer. Moreover, although not illustrated, a plurality of receiving terminals 322B are provided in an array on the bottom surface of the memory device 302B.

The branching wiring 206B includes a via 241B that is electrically connected to the main wiring 216, and a lead-out wiring pattern 242B that connects the via 241B and the land 220B. The other end of the branching wiring 206B is connected to the land 220B formed on the mount surface 222.

The plurality of lands 220B are arranged in an array, and each land 220B is electrically connected to the receiving terminal 322B of the memory device 302B by a connection conductor such as a solder ball not illustrated. The open stub 220BS is connected to the land 220B to which the receiving terminal 322B of the memory device 302B is joined. The open stub 220BS is desirably formed in a meandering manner, as illustrated in FIG. 3, to save space.

The via 241B is arranged outside the land group formed from the plurality of lands 220B, and may be formed to have a relatively large diameter, and thus an inexpensive motherboard 200 is realized. The distance d between the lands 220B is about 0.8 mm pitch, for example.

The wiring length of the branching wiring 206B at this time is about 10 mm at the maximum.

The size of the land of the via 241B that can be used for the inexpensive motherboard 200 illustrated in FIG. 2 is about 0.6 mm, and the size of the land 220B is about 0.4 mm. Accordingly, the via 241B cannot be arranged between the lands 220B at a pitch of 0.8 mm.

Accordingly, the via 241B is arranged on the outside of the memory device 302B. As a result, the length of the branching wiring 206B to the land 220B from the via 241B on the main wiring is increased, and a problem described above that the input voltage condition of a signal is not satisfied is likely to occur.

Also, as described above, there is a propagation delay to the memory cell 321B inside the memory device 302B depending on the package wiring or the internal capacity. This propagation delay is translated into the length on the motherboard 200 and is given as the wiring length of the effective inner wiring 323B (the electric length). Normally, there is a variance of about 10 to 20 mm in the branching wiring length including the wiring length of the effective inner wiring 323B, that is, the total wiring length of the inner wiring 323B and the branching wiring 206B. This total wiring length of the inner wiring 323B and the branching wiring 206B is referred to as the effective branching wiring length.

As described above, the memory system 100₁ is formed by mounting the memory devices 302A to 302D on both sides of the motherboard 200, but a memory system where the memory devices are mounted on one side of the motherboard 200 may also be structured as necessary.

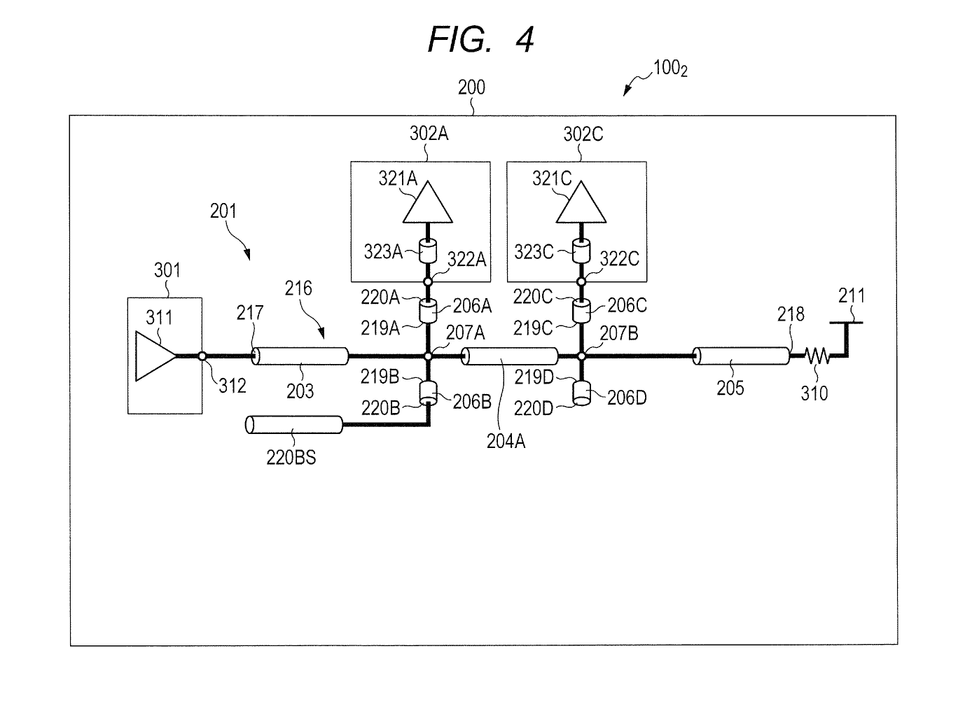

FIG. 4 is an explanatory diagram illustrating a schematic structure of a memory system 100₂ of a single-side mounting structure according to the first embodiment of the present invention. Additionally, structural elements of the memory system 100₂ which are the same as those of the memory system 100₁ are denoted with the same references and description thereof is omitted.

The memory system 100₂ has a single-side mounting structure which is the structure of the memory system 100₁ from which the memory devices 302B and 302D on the mount surface 222 are omitted, and the motherboard 200 of the memory system 100₂ has the same structure as the motherboard 200 of the memory system 100₁. That is, in the first embodiment, the motherboard 200 is common between the memory systems 100₁ and 100₂, and the wiring design of the motherboard 200 does not have to be changed between the double-side mounting memory system 100₁ and the single-side mounting memory system 100₂.

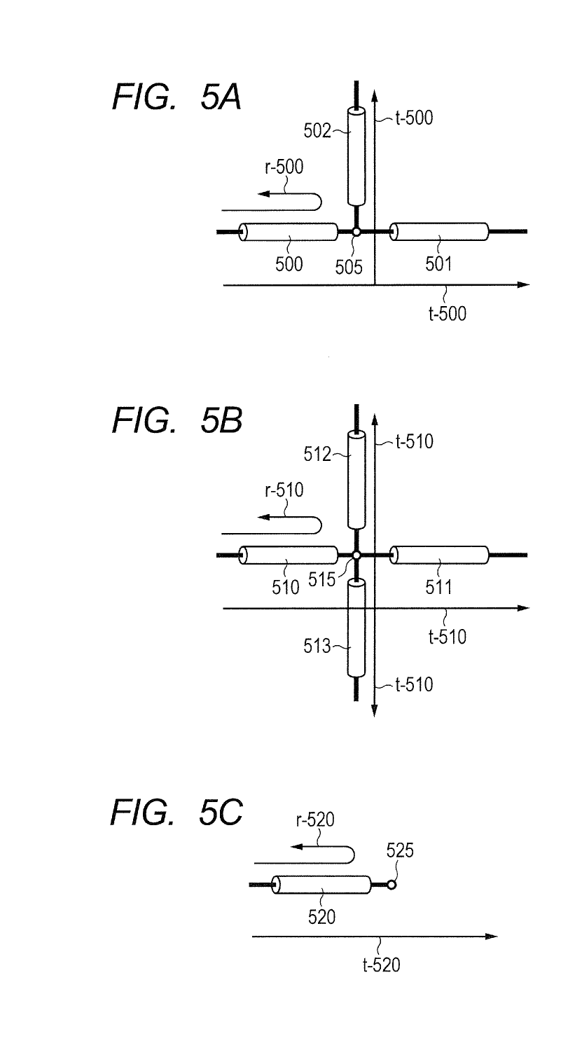

In the following, the received waveform of a signal received at each memory device will be described. FIGS. 5A to 5C are diagrams for describing reflection and transmission of a signal component at a branching point. In FIG. 5A, a wiring 500 with a characteristic impedance Z₁, a wiring 501 with a characteristic impedance Z₂, and a wiring 502 with a characteristic impedance Z₃ are connected at a connection point 505. Also, it is assumed that a signal is conveyed from the wiring 500 side. That is, a signal is branched from the wiring 500 into two, that is, into the wirings 501 and 502. FIG. 5A illustrates a route r-500 along which a signal conveyed from the wiring 500 side returns after being reflected at the connection point 505, and a route t-500 by which the same signal passes through the connection point 505 and is conveyed to the wirings 501 and 502.

A synthesized impedance Zₐ of the wiring 501 and the wiring 502 seen from the wiring 500 side is given by the following expression (1).

$${Z}_{a} = \frac{{Z}_{2} \times {Z}_{3}}{{Z}_{2} + {Z}_{3} } \qquad ( 1 )$$

For example, if the characteristic impedance Z₂ and the characteristic impedance Z₃ are the same as the characteristic impedance Z₁, the synthesized impedance Zₐ is ½ the characteristic impedance Z₁.

The percentage voltage of reflection, at the connection point 505, of a signal conveyed from the wiring 500 side is expressed by the following expression (2).

$$\frac{{Z}_{a} - {Z}_{1}}{{Z}_{a} + {Z}_{1}} \qquad ( 2 )$$

For example, in the case where the synthesized impedance Zₐ is ½ the characteristic impedance Z₁, the value of the expression (2) is −⅓, and −⅓ of the voltage is reflected.

The percentage voltage of transmission, through the connection point 505, of a signal conveyed from the wiring 500 side is expressed by the following expression (3).

$$\frac{2 {Z}_{a}}{{Z}_{a} + {Z}_{1}} \qquad ( 3 )$$

For example, in the case where the synthesized impedance Zₐ is ½ the characteristic impedance Z₁, the value of the expression (3) is ⅔, and ⅔ of the voltage is transmitted.

In FIG. 5B, a wiring 510 with a characteristic impedance Z₁, a wiring 511 with a characteristic impedance Z₂, a wiring 512 with a characteristic impedance Z₃, and a wiring 513 with a characteristic impedance Z₄ are connected at a connection point 515. Also, it is assumed that a signal is conveyed from the wiring 510 side. That is, a signal is branched from the wiring 510 into three, that is, into the wirings 511, 512 and 513. FIG. 5B illustrates a route r-510 along which a signal conveyed from the wiring 510 side returns after being reflected at the connection point 515, and a route t-510 by which the same signal passes through the connection point 515 and is conveyed to the wirings 511, 512 and 513.

A synthesized impedance Zₐ of the wiring 511 and the wiring 512 seen from the wiring 510 side is given by the following expression (4).

$${Z}_{a} = \frac{{Z}_{2} \times {Z}_{3} \times {Z}_{4}}{{Z}_{2} \times {Z}_{3} + {Z}_{2} \times {Z}_{4} + {Z}_{3} \times {Z}_{4}} \qquad ( 4 )$$

For example, if the characteristic impedances Z₂ to Z₄ are the same as the characteristic impedance Z₁, the synthesized impedance Zₐ is ⅓ the characteristic impedance Z₁.

The percentage voltage of reflection, at the connection point 515, of a signal conveyed from the wiring 510 side is expressed by the expression (2) above. For example, in the case where the synthesized impedance Zₐ is ⅓ the characteristic impedance Z₁, the value of the expression (2) is − 1/2, and −½ of the voltage is reflected.

The percentage voltage of transmission, through the connection point 515, of a signal conveyed from the wiring 510 side is expressed by the expression (3) above. For example, in the case where the synthesized impedance Zₐ is ⅓ the characteristic impedance Z₁, the value of the expression (3) is ½, and ½ of the voltage is transmitted.

In FIG. 5C, there is no wiring beyond an end point 525 of a wiring 520 with a characteristic impedance Z₁, and the end is an open end. At a receiving circuit such as a memory device, the internal capacity of a memory cell may be galvanically assumed to be a load with an infinite impedance, and may be approximately treated as an open end.

It is assumed that a signal is conveyed from the wiring 520 side. FIG. 5C illustrates a route r-520 along which a signal conveyed from the wiring 520 side returns after being reflected at the end point 525, and a route t-520 that does not actually exist but virtually passes the end point (the open end) 525.

Since the impedance Zₐ beyond the end point (the open end) 525 seen from the wiring 520 side is infinite, the percentage voltage of reflection, at the end point 525, of a signal conveyed from the wiring 520 side is a limiting value 1 which is obtained when the synthesized impedance Zₐ is made infinite in the expression (2) above. Accordingly, the same voltage as the signal conveyed from the wiring 520 side is reflected.

The percentage voltage of a signal conveyed from the wiring 520 side virtually passing through the end point (the open end) 525 is a limiting value 2 which is obtained when the synthesized impedance Zₐ is made infinite in the expression (3) above, and twofold voltage is transmitted. In the case where there is a receiving circuit at the end point 525, this is taken as the received waveform voltage.

In the following, for the sake of simplicity, the impedances of the wirings are assumed to take the same value, such as 55Ω.

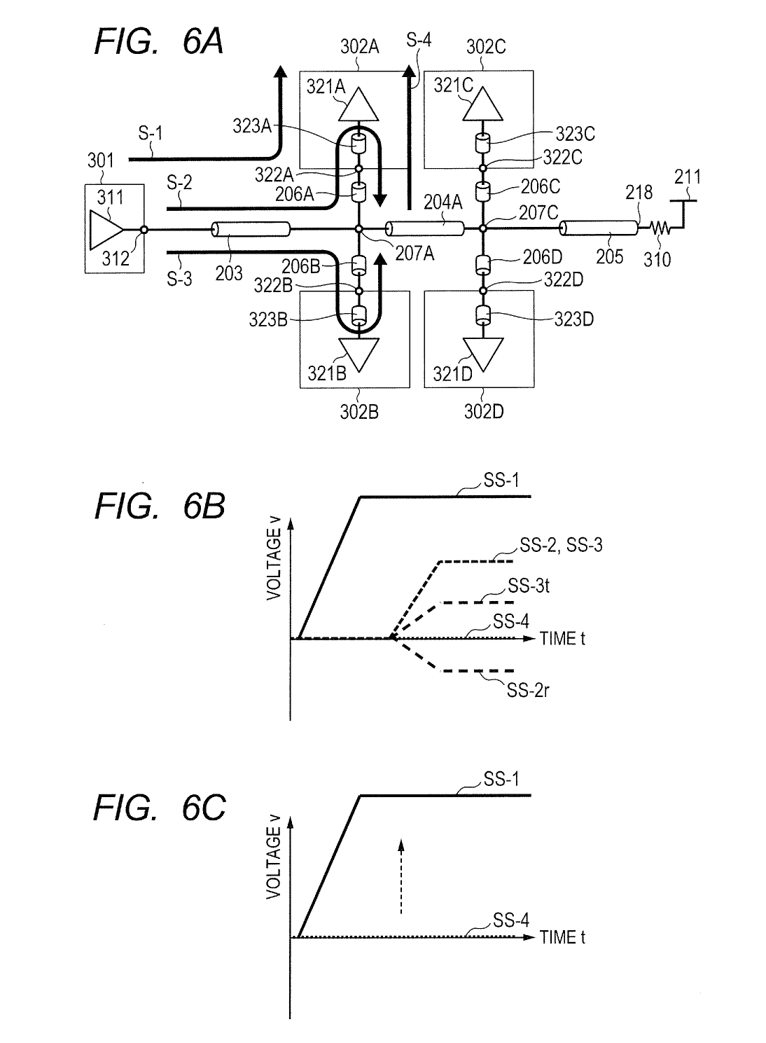

FIGS. 6A to 6C are diagrams for describing a received waveform of the memory device 302A where the memory devices 302A to 302D are mounted on both sides of a motherboard for double-side mounting according to a comparative example. The memory system of this comparative example is the memory system 100₁ from which the open stub 220BS is omitted, and other structural elements are the same as those of the memory system 100₁.

A signal wave from the memory controller 301 reaches the memory device 302A first as a signal SS-1 by a route S-1. At this time, the signal wave is branched into three at the branching point 207A and then passes through the branching wiring 206A, and thus the voltage is made ½.

The reflected wave from the memory cell (an internal circuit end) 321A of the memory device 302A reaches the branching point 207A by a route S-2. The voltage is made ½ at the time of passing through the branching point 207A, and the voltage remains at ½ at the time of reflection at the memory cell 321A of the memory device 302A, and thus the voltage of a signal SS-2 at the time of reaching the branching point 207A again is ½.

The reflected wave from the memory cell 321B of the memory device 302B reaches the branching point 207A by a route S-3. The voltage is made ½ at the time of passing through the branching point 207A, and the voltage remains at ½ at the time of reflection at the memory cell 321B of the memory device 302B, and thus the voltage of a signal SS-3 at the time of reaching the branching point 207A again is ½.

A signal wave SS-4 is conveyed from the branching point 207A to the memory device 302A by a route S-4. This signal wave is a synthesized wave of a reflected wave SS-2r of the signal wave which reached the branching point 207A by the route S-2 and a transmitted wave SS-3t of the signal wave which reached the branching point 207A by the route S-3.

The voltage of the signal wave SS-2r is (½)×(−½)=(−¼). The voltage of the signal wave SS-3t is (½)×(½)=(¼). These two signal waves SS-2r and SS-3t reach the branching point 207A at the same time. However, the voltage of the synthesized wave is zero by an offset, and thus the amplitude of the signal SS-4 conveyed to the memory device 302A by the route S-4 is made zero, and there is no occurrence, at the memory device 302A, of a signal that would cause ringing.

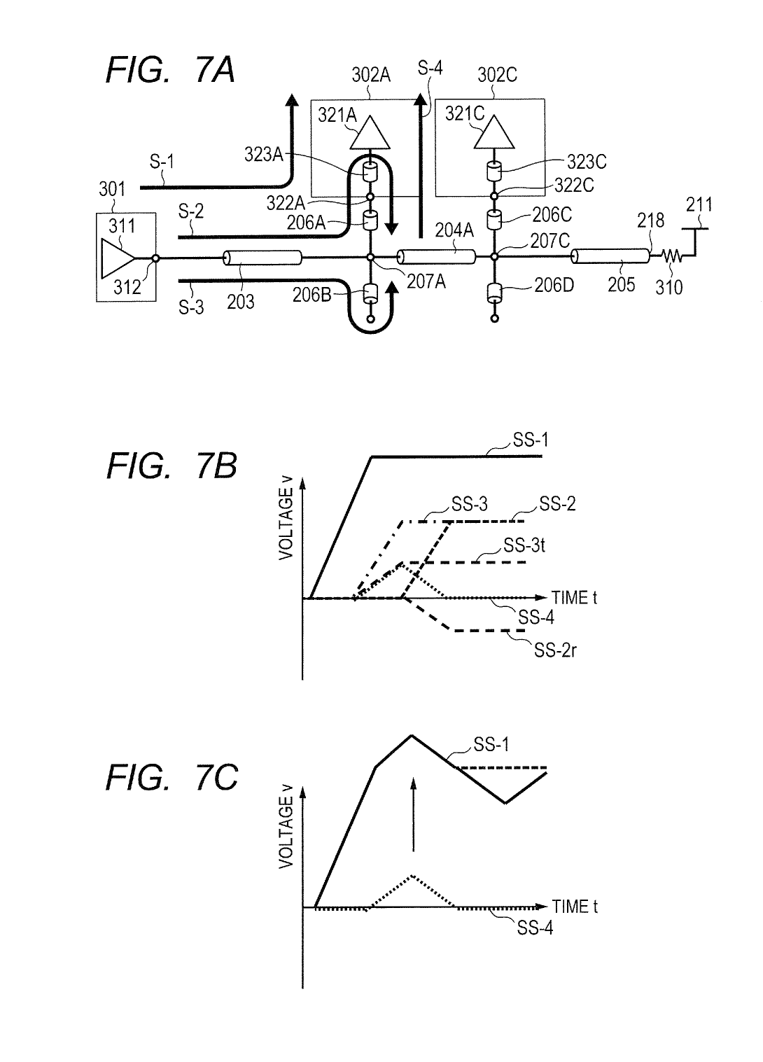

FIGS. 7A to 7C are diagrams for describing a received waveform of the memory device 302A in a single-side mounting state corresponding to a state where the memory devices 302B and 302D in FIG. 6A are not mounted on the motherboard for double-side mounting according to the comparative example of FIGS. 6A to 6C. The memory system of this comparative example is the memory system 100₂ from which the open stub 220BS is omitted, and other structural elements are the same as those of the memory system 100₂.

A signal wave SS-1 that reaches the memory device 302A first by a route S-1 is the same as that in FIG. 6B, and the voltage is ½.

A signal wave SS-2 whose reflected wave from the memory cell (the internal circuit end) 321A of the memory device 302A by a route S-2 reaches the branching point 207A is also the same as that in FIG. 6B, and the voltage at the time of reaching the branching point 207A again is ½.

With a route S-3, the land 220B connected to the branching wiring 206B is the end point, and the reflected wave is to reach the branching point 207A. The voltage is made ½ at the time of passing through the branching point 207A, and the voltage remains at ½ at the time of reflection at the land 220B, and thus the voltage of a signal wave SS-3 at the time of reaching the branching point 207A again is ½.

A signal wave SS-4 is conveyed from the branching point 207A to the memory device 302A by a route S-4. This signal wave is a synthesized wave of a reflected wave SS-2r of the signal wave SS-2 which reached the branching point 207A by the route S-2 and a transmitted wave SS-3t of the signal wave SS-3 which reached the branching point 207A by the route S-3.

The voltage of the reflected wave of the signal wave SS-2r is (½)×(−½)=(−¼). The voltage of the transmitted wave of the signal wave SS-3t is (½)×(½)=(¼).

Due to absence of an inner wiring in the memory device, the signal wave SS-3t reaches the branching point 207A earlier than the signal wave SS-2r. Accordingly, the signal wave SS-4 that is conveyed to the memory device 302A by the route S-4 will have a voltage (¼), and ringing is caused in the received signal of the memory device 302A.

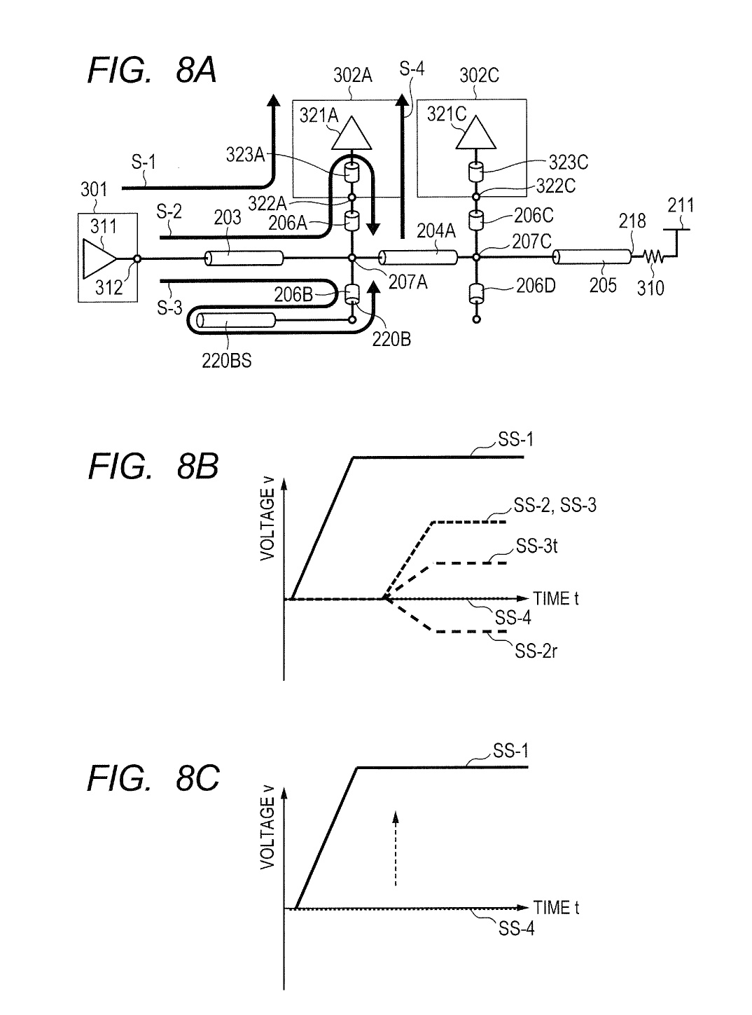

FIGS. 8A to 8C are diagrams for describing a received waveform of the memory device 302A of the memory system 100₂ in a single-side mounting state where the memory devices 302B and 302D are not mounted on the other mount surface 222 (FIG. 2) of the motherboard 200 illustrated in FIG. 4. In FIG. 8A, the open stub 220BS is connected to the land 220B connected to the branching wiring 206B, and the effective wiring length (electric length) is made the same as the inner wiring 323A of the memory device 302A.

A signal wave SS-1 that reaches the memory device 302A first by a route S-1 is the same as that in FIG. 6B, and the voltage is ½.

A signal wave SS-2 whose reflected wave from the internal circuit end of the memory device 302A by a route S-2 reaches the branching point 207A is also the same as that in FIG. 6B, and the voltage at the time of reaching the branching point 207A again is ½.

With a route S-3, the open end of the open stub 220BS that is connected to the land 220B connected to the branching wiring 206B is the end point, and the reflected wave is to reach the branching point 207A. The voltage is made ½ at the time of passing through the branching point 207A, and the voltage remains ½ at the time of reflection at the land 220B, and thus the voltage of a signal wave SS-3 at the time of reaching the branching point 207A again is ½.

A signal wave SS-4 is conveyed from the branching point 207A to the memory device 302A by a route S-4. This signal wave is a synthesized wave of a reflected wave SS-2r of the signal wave SS-2 which reached the branching point 207A by the route S-2 and a transmitted wave SS-3t of the signal wave SS-3 which reached the branching point 207A by the route S-3.

The voltage of the signal wave SS-2r is (½)×(−½)=(−¼). The voltage of the signal wave SS-3t is (½)×(½)=(¼).

The signal wave SS-3t reaches the branching point 207A at the same time as the signal wave SS-2r by passing through the open stub 220BS. Accordingly, the voltage of the synthesized wave SS-4 is zero due to an offset between the signal wave SS-2r and the signal wave SS-3t, and occurrence of ringing in the signal reaching the memory device 302A is suppressed.

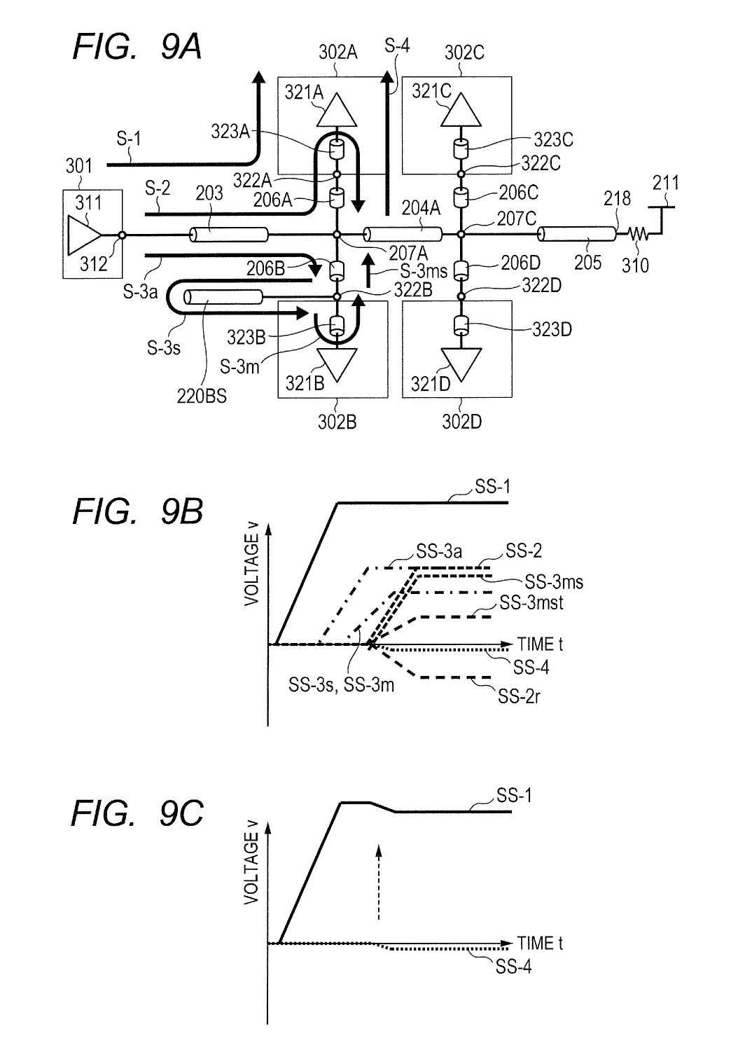

FIGS. 9A to 9C are diagrams for describing a received waveform of the memory device 302A where memory devices are mounted on both sides of the motherboard 200 according to the first embodiment of the present invention.

A signal wave SS-1 that reaches the memory device 302A first by a route S-1 is the same as that in FIG. 6B, and the voltage is ½.

A signal wave SS-2 whose reflected wave from the memory cell (the internal circuit end) 321A of the memory device 302A by a route S-2 reaches the branching point 207A is also the same as that in FIG. 6B, and the voltage at the time of reaching the branching point 207A again is ½.

The voltage of a signal wave SS-3a that reaches the land 220B by a route S-3a becomes ½ at the time of passing through the branching point 207A.

The voltage of a signal wave that is transmitted to the open stub 220BS by a route S-3s is (½)×(⅔)=⅓, and the voltage of a signal wave SS-3s that is returned to the land 220B via the open end of the open stub 220BS is ⅓.

The voltage of a signal wave SS-3m that is reflected at the memory cell (the internal circuit end) 321B of the memory device 302B and is returned to the land 220B by a route S-3m is also ⅓.

The signal wave SS-3ms that is returned from the land 220B to the branching point 207A by the route S-3ms is a synthesized wave of the transmitted wave of the signal wave SS-3s and the transmitted wave of the signal wave SS-3m.

The voltage of the signal wave SS-3s is (⅓)×(⅔)= 2/9. The voltage of the signal wave SS-3m is (⅓)×(⅔)= 2/9. Accordingly, the voltage of the synthesized wave SS-3ms is 4/9.

A signal wave SS-4 is conveyed from the branching point 207A to the memory device 302A by a route S-4. This signal wave is a synthesized wave of a reflected wave SS-2r of the signal wave SS-2 which reached the branching point 207A by the route S-2 and a transmitted wave SS-3mst of the signal wave SS-3ms which reached the branching point 207A by the route S-3ms.

The voltage of the signal wave SS-2r is (−½)×(½)=(−¼). The voltage of the signal wave SS-3mst is ( 4/9)×(½)= 2/9. Accordingly, the voltage of the synthesized wave SS-4 is (−¼)+( 2/9)=(− 1/36).

This is about 3% of the voltage of an output signal wave of the memory controller 301, and hardly causes ringing in the received waveform of the memory device 302A.

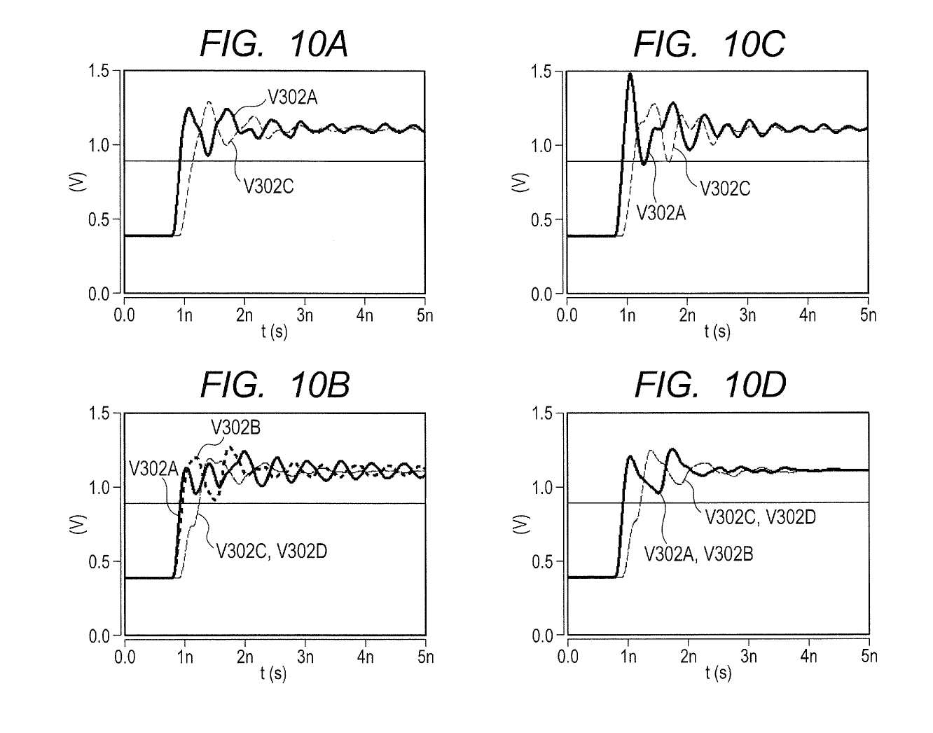

FIGS. 10A to 10D are waveform diagrams illustrating results of performing simulation on the memory system according to the first embodiment of the present invention in a single-side mounting state and in a double-side mounting state, and a memory system according to the comparative example in a single-side mounting state and in a double-side mounting state.

FIG. 10A is a waveform diagram illustrating the result of performing simulation on the memory system according to the first embodiment of the present invention in a single-side mounting state. FIG. 10A takes, as the simulation model, the memory system 100₂ illustrated in FIG. 4 having the memory devices 302A and 302C mounted on the mount surface 221 of the motherboard 200 and not having mounted the memory devices 302B and 302D.

FIG. 10B is a waveform diagram illustrating the result of performing simulation on the memory system according to the first embodiment of the present invention in a double-side mounting state. FIG. 10B takes, as the simulation model, the memory system 100₁ illustrated in FIG. 1 having the memory devices 302A and 302C mounted on the mount surface 221 of the motherboard 200 and the memory devices 302B and 302D mounted on the mount surface 222 of the motherboard 200.

FIG. 10C is a waveform diagram illustrating the result of performing simulation on the memory system according to the comparative example in a single-side mounting state, and takes, as the simulation model, the memory system which is the memory system 100₂ illustrated in FIG. 4 from which the open stub 220BS is omitted.

FIG. 10D is a waveform diagram illustrating the result of performing simulation on the memory system according to the comparative example in a double-side mounting state, and takes, as the simulation model, the memory system which is the memory system 100₁ illustrated in FIG. 1 from which the open stub 220BS is omitted.

The voltage of a signal (pulse) to be transmitted by the memory controller 301 is 1.5V, and the rise time is 100 psec. As the buffer model of the memory controller 301, a DQ signal model based on the IBIS model of a DDR3 memory is used.

The characteristic impedances of the wirings are all 55Ω. The wiring length of the wiring 203 is 55 mm, the wiring length of the wiring 204A is 18 mm, and the wiring length of the wiring 205 is 14 mm. The resistance value of the terminating end resistor 310 is 36Ω, and the terminating end potential applied to the terminating end wiring 211 is 0.75V. The wiring lengths of the branching wirings 206A to 206D are 9 mm. The models for the memory devices 302A to 302D use the model of an AD signal.

As the simulation tool, HSPICE of Synopsys, Inc. is used. As the determination reference voltage for a received waveform, 0.89V which is obtained by adding 40 mV to a threshold voltage 0.85V according to the DDR3 standard is used based on the empirical findings by the inventors.

FIGS. 10A to 10D also illustrate a line at the determination reference voltage 0.89V. In FIGS. 10A to 10D, the waveform of a signal received by the memory device 302A is given as V302A. The waveform of a signal received by the memory device 302B is given as V302B. The waveform of a signal received by the memory device 302C is given as V302C. The waveform of a signal received by the memory device 302D is given as V302D.

As illustrated in FIG. 10A, with the memory system 100₁ of single-side mounting according to the first embodiment, ringing of the signal exceeds the determination reference voltage 0.89V and the voltage margin of the signal is secured for both the memory devices 302A and 302C. Also, as illustrated in FIG. 10B, with the memory system 100₂ of double-side mounting according to the first embodiment, ringing of the signal exceeds the determination reference voltage 0.89V and the voltage margin of the signal is secured for all the memory devices 302A to 302D.

That is, according to the structure of the first embodiment where the open stub 220BS is provided, the voltage margin of a signal received by a memory device is secured regardless of whether mounting is single-side mounting or double-side mounting.

On the other hand, as illustrated in FIG. 10C, with the memory system of single-side mounting according to the comparative example, ringing of the signal falls below the determination reference voltage 0.89V and the voltage margin of the signal is not secured for both the memory devices 302A and 302C. Moreover, as illustrated in FIG. 10D, with the memory system of double-side mounting according to the comparative example, ringing of the signal exceeds the determination reference voltage 0.89V and the voltage margin of the signal is secured for all the memory devices 302A to 302D.

That is, according to the structure of the comparative example where the open stub 220BS is not provided, the voltage margins of the signals received by the memory devices 302A to 302D are secured in the case of double-side mounting. However, in the case of single-side mounting, the voltage margin of the received signal is secured for neither the memory device 302A nor 302B.

The result of simulation for a case where the length (the electric length) of the open stub 220BS is changed will be described. An inductance value L of the internal line of an AD signal package is given as 1.921 nH, a capacitance value C as 0.57 pF, and an input capacity Ccomp of a receive buffer as 0.616 pF.

When assuming that the internal line inside the AD signal package to be a distributed constant transmission line model, the propagation delay time td is determined by √(L·C)=√(1.921 [nH]×(0.57 [pF]+0.616 [pF]))≈47.7 [psec]. When the signal transmission speed at the motherboard 200 is assumed to be 6 psec/mm and is translated into an effective wiring length, 47.7 [psec]÷6 [psec/mm]≈8 [mm] is true. That is, the effective electric length of the inner wiring 323A including the capacitive component of the memory device 302A (especially, the capacity load at the memory cell 321A) is 8 mm.

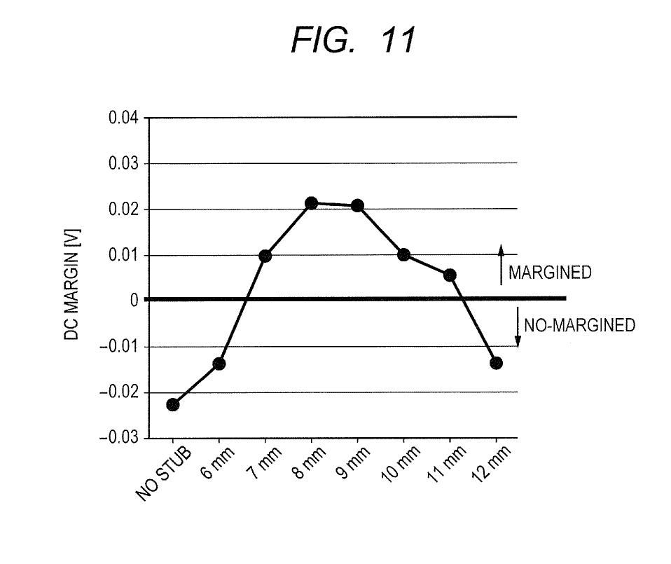

FIG. 11 is a graph illustrating a difference of a minimum voltage of ringing to the determination reference voltage in a case where the electric length of the open stub 220BS is changed. FIG. 11 is a result of performing simulation with the effective wiring length (electric length) of the inner wiring 323A in the package being 8 mm. The length of the open stub 220BS is changed stepwise by 1 mm from 6 mm to 12 mm, and the differences of the minimum voltage of ringing of a signal waveform with respect to the determination reference voltage 0.89 V are determined and plotted as black dots as illustrated in FIG. 11. In FIG. 11, a greater positive value of the difference means a greater margin. Additionally, here, the values of smaller margins between single-side mounting and double-side mounting are adopted and plotted.

As illustrated in FIG. 11, the margin is great where the electric length of the open stub 220BS is 8 mm, that is, around the effective wiring length (electric length) of the inner wiring 323A in the package. Thus, the open stub 220BS achieves an effect of improving the ringing at the range of 7 mm to 10 mm in FIG. 11.

That is, the margin is secured when the electric length of the open stub 220BS is set to within the range of −10% to +30% of the electric length of the effective inner wiring 323A including the capacitive components of the memory device 302A.

According to FIG. 11, the ringing suppression effect is the highest when the electric length of the open stub 220BS is made the same as the electric length of the effective inner wiring 323A including the capacitive components of the memory device 302A. Also, ringing may be effectively suppressed if the electric length of the open stub 220BS is within the range of −10% to +30% of the electric length of the effective inner wiring 323A including the capacitive components of the memory device 302A.

As described above, according to the first embodiment, occurrence of ringing in a signal that is received by each memory device mounted may be suppressed for both the memory system 100₁ of double-side mounting and the memory system 100₂ of single-side mounting. That is, occurrence of ringing in signals that are received by memory devices may be suppressed even when the motherboard 200 of the same (common) structure is used by the memory systems 100₁ and 100₂, regardless of whether the memory devices 302B and 302D are mounted or not. Occurrence of ringing in a signal that is received by the memory device 302A is especially effectively suppressed. Accordingly, the motherboard 200 may be made common between the memory systems 100₁ and 100₂, and the burden required to manufacture the memory systems 100₁ and 100₂ may be reduced.

Additionally, the effective wiring length (electric length) of the inner wiring 323A of the memory device 302A may also be determined by measuring the actual memory part by a TDR oscilloscope instead of by the method of determination based on the contents of description of the IBIS model described above.

### Second Embodiment

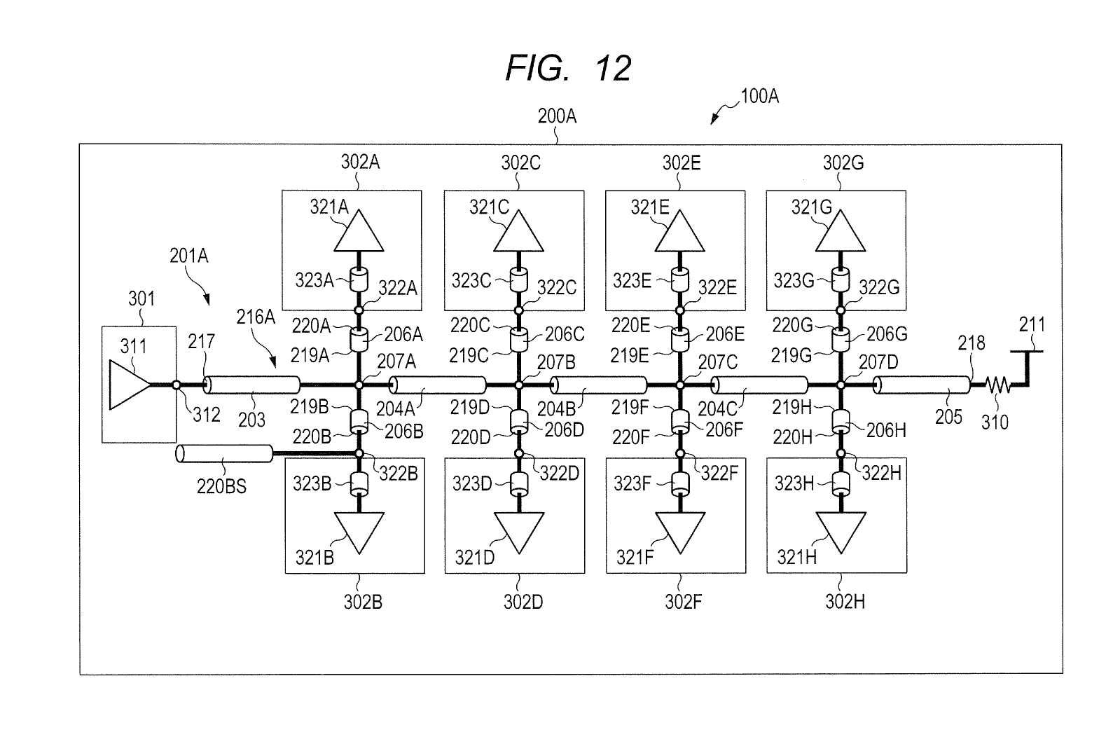

Next, a memory system which is an example of a printed circuit board according to a second embodiment of the present invention will be described. FIG. 12 is a topology diagram illustrating a wiring structure of a memory system as an example of a printed circuit board according to the second embodiment of the present invention. Additionally, in the second embodiment, structural elements which are the same as those of the memory system of the first embodiment described above are denoted with the same references and description thereof is omitted.

A memory system 100A which is a printed circuit board includes a motherboard 200A which is a printed wiring board, a memory controller 301 which is a transmitting circuit, and a plurality of memory devices 302A to 302H which are a plurality of receiving circuits. In the second embodiment, as in the first embodiment, the memory devices 302A to 302H are DDR3-SDRAMs. The memory controller 301 and the memory devices 302A to 302H are BGA semiconductor packages.

The memory controller 301 and the plurality of memory devices 302A to 302H are mounted on the motherboard 200A. FIG. 12 illustrates a double-side mounting structure where the memory devices are mounted on both sides of the motherboard 200A.

The memory devices 302A to 302H are semiconductor packages respectively including memory cells 321A to 321H each being formed from a semiconductor element which is a receiving element, and receiving terminals 322A to 322H connected to the memory cells 321A to 321H via inner wirings 323A to 323H. The memory devices 302A to 302H are semiconductor packages having the same structure and the same property.

Additionally, the inner wirings 323A to 323H are effective inner wirings of the memory devices 302A to 302H. That is, depending on the length of a package wiring and the capacitive components of the memory cells 321A to 321H, a propagation delay occurs, in the memory devices 302A to 302H, in the signals propagated from the receiving terminals 322A to 322H to the memory cells 321A to 321H. This propagation delay is translated into the length of a wiring pattern on the motherboard 200A and is given as the length of the effective inner wirings (the electric length) of the memory devices 302A to 302H, and these inner wirings are illustrated as the inner wirings 323A to 323H in FIG. 12.

As illustrated in FIG. 12, the motherboard 200A, which is the printed wiring board of the memory system 100A, includes a bus wiring 201A that connects the memory controller 301 and the memory devices 302A to 302H by a fly-by method.

The bus wiring 201A includes a main wiring 216A whose leading end 217 is electrically connected to a transmitting terminal 312 of the memory controller 301, and whose terminating end 218 is electrically connected to one end of a terminating end resistor 310.

The main wiring 216A is formed extending in the wiring direction from the leading end 217 to the terminating end 218 in the shape of unicursal line.

The bus wiring 201A includes a plurality of branching wirings (first branching wirings) 206A, 206C, 206E and 206G branched, respectively, from a plurality of branching points 207A to 207D at different positions on the main wiring 216A. Of the plurality of branching points 207A to 207D, the branching point closest to the leading end 217 is the branching point 207A.

The bus wiring 201A also includes a branching wiring (a second branching wiring) 206B branched from the branching point 207A. The bus wiring 201A further includes branching wirings (third branching wirings) 206D, 206F and 206H branched from the branching points 207B, 207C and 207D other than the branching point 207A.

Memory devices may be connected to all the branching wirings 206A, 206C, 206E and 206G that are formed extending to one of a pair of mount surfaces of the motherboard 200A. In the second embodiment, memory devices 302A, 302C, 302E and 302G are connected to the branching wirings 206A, 206C, 206E and 206G.

Additionally, memory devices may be connected to the branching wirings 206B, 206D, 206F and 206H that are formed extending to the other mount surface of the pair of mount surfaces of the motherboard 200A, but the memory devices do not actually have to be connected. That is, memory devices do not have to be mounted on the other mount surface. Thus, at least one (some or all) of the memory devices 302B, 302D, 302F and 302H may be omitted. In the second embodiment, the memory devices 302B, 302D, 302F and 302H are connected to all the branching wirings 206B, 206D, 206F and 206H that are formed extending to the other mount surface 222.

That is, the memory device 302A is electrically connected to the branching wiring 206A, the memory device 302B to the branching wiring 206B, the memory device 302C to the branching wiring 206C, and the memory device 302D to the branching wiring 206D. Also, the memory device 302E is electrically connected to the branching wiring 206E, the memory device 302F to the branching wiring 206F, the memory device 302G to the branching wiring 206G, and the memory device 302H to the branching wiring 206H.

Specifically, one end 219A of the branching wiring 206A in the wiring direction and one end 219B of the branching wiring 206B in the wiring direction are electrically connected to the branching point 207A. Also, one end 219C of the branching wiring 206C in the wiring direction and one end 219D of the branching wiring 206D in the wiring direction are electrically connected to the branching point 207B.

Furthermore, one end 219E of the branching wiring 206E in the wiring direction and one end 219F of the branching wiring 206F in the wiring direction are electrically connected to the branching point 207C. Also, one end 219G of the branching wiring 206G in the wiring direction and one end 219H of the branching wiring 206H in the wiring direction are electrically connected to the branching point 207D.

Also, other ends 220A to 220H of the respective branching wirings 206A to 206H in the wiring direction are electrically connected to the receiving terminals 322A to 322H of the respective memory devices 302A to 302H.

The other ends 220A to 220H of the branching wirings 206A to 206H are formed by lands (hereinafter, the other end(s) will be referred to as “land(s)”). The receiving terminals 322A to 322H of the memory devices 302A to 302H are joined to the lands 220A to 220H, respectively, by solders or the like. That is, the lands 220A to 220H of the branching wirings 206A to 206H are formed in such a way as to allow joining of the receiving terminals 322A to 322H of the memory devices 302A to 302H.

Here, the branching wiring 206E is the branching wiring extending to the front layer side (a front layer side branching wiring), and the branching wiring 206F is the branching wiring extending to the back layer side (a back layer side branching wiring). Also, the branching wiring 206G is the branching wiring extending to the front layer side (a front layer side branching wiring), and the branching wiring 206H is the branching wiring extending to the back layer side (a back layer side branching wiring). The branching wirings 206A to 206H have about the same length (the electric length).

The main wiring 216A includes a wiring 203 between the leading end 217 and the branching point 207A, a wiring 204A between the branching point 207A and the branching point 207B, and a wiring 204B between the branching point 207B and the branching point 207C. Also, the main wiring 216A includes a wiring 204C between the branching point 207C and the branching point 207D. Furthermore, the main wiring 216A includes a wiring 205 between the branching point 207C and the terminating end 218.

The main wiring 216A is formed on the inner layer or the front and back layers of the motherboard 200A, and the branching wirings 206A, 206C, 206E and 206G are formed across the inner layer and the front layer of the motherboard 200A. The branching wirings 206B, 206D, 206F and 206H are formed across the inner layer and the back layer of the motherboard 200A.

As in the first embodiment, an open stub 220BS is formed extending from the land 220B, of the branching wiring 206B, to which the receiving terminal 322B of the memory device 302B is joined. One end of the open stub 220BS in the wiring direction is electrically connected to the land 220B, and the other end of the open stub 220BS is an open end that is open. The open stub 220BS is formed on the other mount surface of the pair of mount surfaces of the motherboard 200A.

The electric length of the open stub 220BS in the wiring direction is set to be substantially the same as the electric length of the inner wiring 323A.

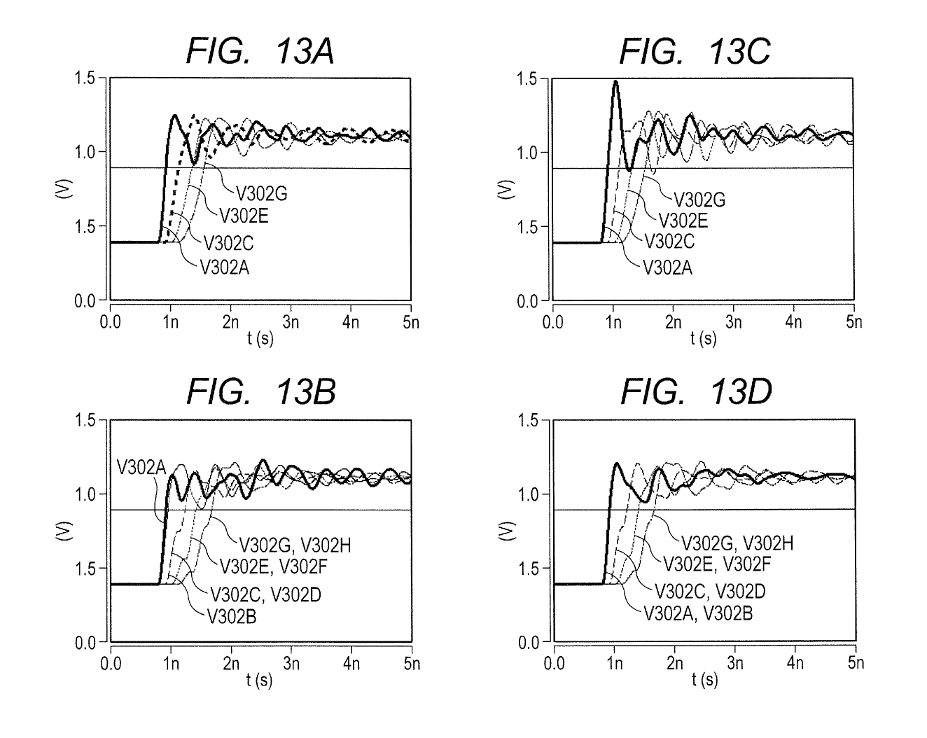

FIGS. 13A to 13D are waveform diagrams illustrating results of performing simulation on the memory system according to the second embodiment of the present invention in a single-side mounting state and in a double-side mounting state, and a memory system according to a comparative example in a single-side mounting state and in a double-side mounting state.

FIG. 13A is a waveform diagram illustrating the result of performing simulation on the memory system according to the second embodiment of the present invention in a single-side mounting state. That is, a memory system having the memory devices 302A, 302C, 302E and 302G mounted on one mount surface of the motherboard 200A and not having mounted the memory devices 302B, 302D, 302F and 302G is taken as the simulation model.

FIG. 13B is a waveform diagram illustrating the result of performing simulation on the memory system according to the second embodiment of the present invention in a double-side mounting state. That is, a memory system having the memory devices 302A, 302C, 302E and 302G mounted on one mount surface of the motherboard 200A and having the memory devices 302B, 302D, 302F and 302G mounted on the other mount surface is taken as the simulation model.

FIG. 13C is a waveform diagram illustrating the result of performing simulation on the memory system according to the comparative example in a single-side mounting state. A memory system obtained by omitting the open stub 220BS from the simulation model of the memory system in FIG. 13A is taken as the simulation model.

FIG. 13D is a waveform diagram illustrating the result of performing simulation on the memory system according to the comparative example in a double-side mounting state. A memory system obtained by omitting the open stub 220BS from the simulation model of the memory system in FIG. 13B is taken as the simulation model.

FIGS. 13A to 13D also illustrate a line at a determination reference voltage 0.89V. In FIGS. 13A to 13D, the waveform of a signal received by the memory device 302A is given as V302A. The waveform of a signal received by the memory device 302B is given as V302B. The waveform of a signal received by the memory device 302C is given as V302C. The waveform of a signal received by the memory device 302D is given as V302D. The waveform of a signal received by the memory device 302E is given as V302E. The waveform of a signal received by the memory device 302F is given as V302F. The waveform of a signal received by the memory device 302G is given as V302G. The waveform of a signal received by the memory device 302H is given as V302H.

As illustrated in FIG. 13A, with the memory system of single-side mounting according to the second embodiment, ringing of the signal exceeds the determination reference voltage 0.89V and the voltage margin of the signal is secured for all the memory devices 302A, 302C, 302E and 302G. Also, as illustrated in FIG. 13B, with the memory system of double-side mounting according to the second embodiment, ringing of the signal exceeds the determination reference voltage 0.89V and the voltage margin of the signal is secured for all the memory devices 302A to 302H.

That is, according to the structure of the second embodiment where the open stub 220BS is provided, the voltage margin of the signal received by each memory device is secured regardless of whether mounting is single-side mounting or double-side mounting.

On the other hand, as illustrated in FIG. 13C, with the memory system of single-side mounting according to the comparative example, ringing of the signal falls below the determination reference voltage 0.89V and the voltage margin of the signal is not secured for all the memory devices 302A, 302C, 302E and 302G. Moreover, as illustrated in FIG. 13D, with the memory system of double-side mounting according to the comparative example, ringing of the signal exceeds the determination reference voltage 0.89V and the voltage margin of the signal is secured for all the memory devices 302A to 302H.

That is, according to the structure of the comparative example where the open stub 220BS is not provided, the voltage margins of the signals received by the memory devices 302A to 302H are secured in the case of double-side mounting. However, in the case of single-side mounting, the voltage margins of the received signals are not secured for the memory devices 302A and 302G.

As described above, according to the second embodiment, occurrence of ringing in a signal that is received by each memory device mounted may be suppressed for both the memory system of double-side mounting and the memory system of single-side mounting. That is, occurrence of ringing in signals that are received by memory devices may be suppressed even when the motherboard 200A of the same (common) structure is used, regardless of whether the memory devices 302B, 302D, 302F and 302H are mounted on the other mount surface or not. Occurrence of ringing in a signal that is received by the memory device 302A is especially effectively suppressed. Accordingly, the motherboard 200A may be made common between the memory systems of single-side mounting and double-side mounting, and the burden required to manufacture the memory systems may be reduced.

Additionally, a case is described above where the branching wirings 206D, 206F and 206H, which are the third branching wirings, are branched from all the branching points 207B, 207C and 207D other than the branching point 207A, as illustrated in FIG. 12, but this is not restrictive.

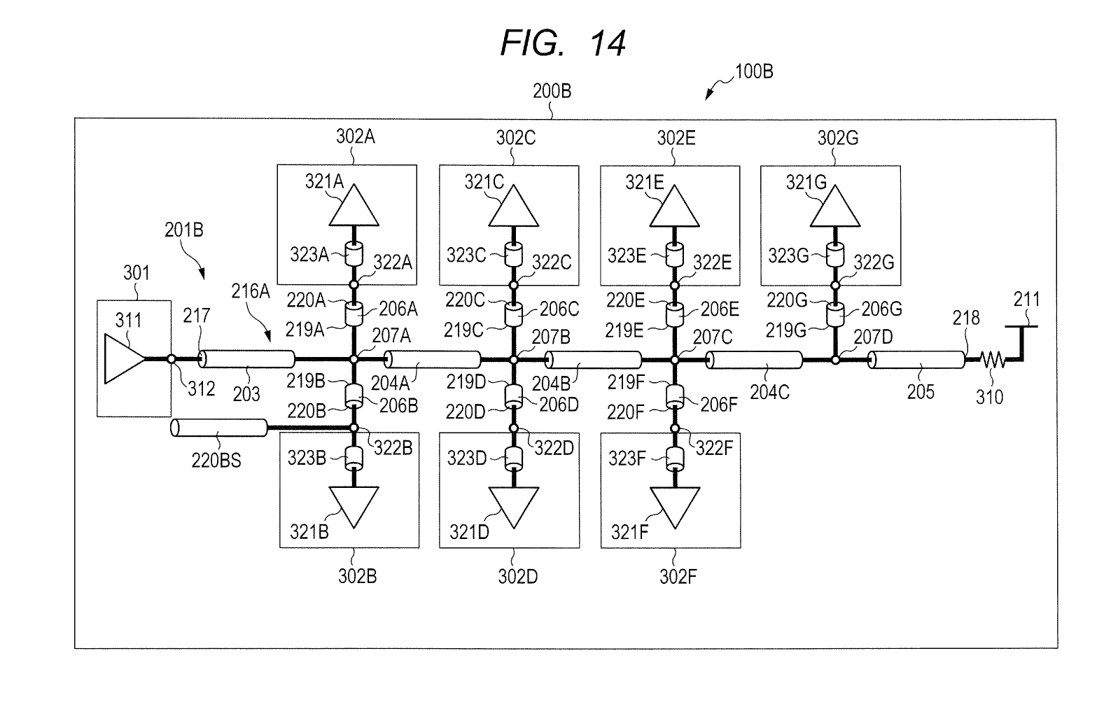

FIG. 14 is a topology diagram illustrating a wiring structure of an example modification of the memory system as an example of the printed circuit board according to the second embodiment of the present invention.

The third branching wirings branched from branching points other than the branching point 207A may be omitted from a motherboard 200B of a memory system 100B illustrated in FIG. 14. For example, as illustrated in FIG. 14, a bus wiring 201B may be structured by omitting the branching wiring 206H from the bus wiring 201A in FIG. 12. In the case of mounting the memory devices on both sides with the structure of this bus wiring 201B, the memory device 302H illustrated in FIG. 12 is omitted.

Also in such a case, ringing of signals may be suppressed for the memory devices 302A to 302G, especially, the memory device 302A, and margins may be secured for the signals.

Additionally, the present invention is not restricted to the embodiments described above, and various modifications may be made within the technical idea of the present invention.

In the embodiments described above, cases are described where a printed circuit board is the memory system and a printed wiring board is the motherboard where the memory device and the memory controller are mounted, but this is not restrictive. The printed circuit board may be a memory module (DIMM) formed from a module substrate as the printed wiring board, and a memory device mounted on the module substrate. In this case, the memory controller is mounted on the motherboard, and the memory controller and the memory device are electrically connected by the memory module being connected to the motherboard by a connector or the like.

Furthermore, in the embodiments described above, cases are described where a plurality of first receiving circuits are mounted on one of the mount surfaces of the printed wiring board, but the number of first receiving circuits may be one.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2014-124973, filed Jun. 18, 2014, which is hereby incorporated by reference herein in its entirety.

What is claimed is:

1. A printed circuit board comprising:
a printed wiring board having a mount surface on which a transmission line is formed;
a transmitting circuit mounted on the mount surface;
a first receiving circuit mounted on the mount surface, and receiving a signal transmitted from the transmitting circuit through the transmission line formed on the printed wiring board; and
a second receiving circuit mounted on the mount surface, and receiving a signal transmitted from the transmitting circuit through the transmission line formed on the printed wiring board, wherein
the transmission line comprises:
a main wiring configured to transmit the signal from the transmitting circuit;
a first branching wiring branched from a first branching point of the main wiring, and connected to the first receiving circuit;
a second branching wiring branched from the first branching point, and connected to the second receiving circuit; and
an open stub branched from the second branching wiring.

2. A printed circuit board comprising:
a printed wiring board having a pair of mount surfaces, on which a transmission line is formed;
a transmitting circuit mounted on one or the other of the pair of mount surfaces;
a first receiving circuit mounted on the one of the pair of mount surfaces, and receiving a signal transmitted from the transmitting circuit through the transmission line formed on the printed wiring board; and
a second receiving circuit mounted on the other of the pair of mount surfaces, and receiving a signal transmitted from the transmitting circuit through the transmission line formed on the printed wiring board, wherein
the transmission line comprises:
a main wiring configured to transmit the signal from the transmitting circuit;
a first branching wiring branched from a first branching point of the main wiring, and connected to the first receiving circuit;
a second branching wiring branched from the first branching point, and connected to the second receiving circuit; and
an open stub branched from the second branching wiring.

3. A printed circuit board comprising:
a printed wiring board having a pair of mount surfaces, on which a transmission line is formed;
a transmitting circuit mounted on one or the other of the pair of mount surfaces;
a first receiving circuit mounted on the one of the pair of mount surfaces, and receiving a signal transmitted from the transmitting circuit through the transmission line formed on the printed wiring board; and
a second receiving circuit mounted on the other of the pair of mount surfaces, and receiving a signal transmitted from the transmitting circuit through the transmission line formed on the printed wiring board, wherein
the transmission line comprises:
a main wiring configured to transmit the signal from the transmitting circuit;
a first branching wiring branched from a first branching point of the main wiring, and connected to the first receiving circuit through a land formed on the one of the pair of mount surfaces;
a second branching wiring branched from the first branching point, and connected to the second receiving circuit through a land formed on the other surface; and
an open stub having one end connected to the land formed on one or the other of the pair of the mount surfaces.

4. The printed circuit board according to claim 3, wherein
the first and second receiving circuits have substantially a same function.

5. The printed circuit board according to claim 3, wherein
the main wiring is formed on the one of the pair of mount surfaces, and
the second branching wiring has a via penetrating between the one and the other of the pair of mount surfaces provided at the first branching point and has a wiring pattern formed on the other of the pair of mount surfaces.

6. The printed circuit board according to claim 3, wherein
the main wiring is formed in an inner layer inside of the printed wiring board,
the first branching wiring has an area, from the first branching point to the one of the pair of the mount surfaces, of a via penetrating between the one and the other of the pair of mount surfaces provided at the first branching point, and has a wiring pattern formed on the other of the pair of mount surfaces,
the second branching wiring has an area, of the via, from the first branching point to the other of the pair of the mount surfaces, and has a wiring pattern formed on the other of the pair of mount surfaces.

7. The printed circuit board according to claim 3, wherein
a second branching point of the main wiring is provided at a side of the first branching point opposite to the transmitting circuit,
a third branching wiring is branched from the second branching point and is connected to a third receiving circuit,
a fourth branching wiring is branched from the second branching point and is connected to a fourth receiving circuit, and
the first to fourth receiving circuits have substantially a same function.

8. The printed circuit board according to claim 3, wherein
the open stub has an electrical length set within a range −10% to +30% of an electrical length of an effective inner wiring including a capacitive component of the first receiving circuit.

9. The printed circuit board according to claim 3, wherein
the first and second receiving circuits are memory devices, and
the transmitting circuit is a memory controller configured to control the memory device.

10. The printed circuit board according to claim 9, wherein
the memory device is DDR3-SDRAM.

11. The printed circuit board according to claim 9, wherein
the main wiring is formed in a shape of unicursal line, a leading end of the unicursal line is connected to the transmitting circuit, and a terminated end of the unicursal line is connected to a terminating end resistor.

12. A printed circuit board comprising:
a printed wiring board having a pair of mount surfaces, on which a transmission line is formed;
a transmitting terminal formed on one or the other of the pair of mount surfaces, and inputting a signal from an external transmitting circuit;
a first receiving circuit mounted on the one of the pair of mount surfaces, and receiving a signal transmitted from the transmitting terminal through the transmission line formed on the printed wiring board; and
a second receiving circuit mounted on the other of the pair of mount surfaces, and receiving a signal transmitted from the transmitting terminal through the transmission line formed on the printed wiring board, wherein
the transmission line comprises:
a main wiring configured to transmit the signal received by the transmitting circuit from the external transmitting circuit;
a first branching wiring branched from a first branching point of the main wiring, and connected to the first receiving circuit;
a second branching wiring branched from the first branching point, and connected to the second receiving circuit through a land formed on the other of the pair of mount surfaces; and
an open stub having one end connected to the land.

13. A printed circuit board comprising:
a printed wiring board having a pair of mount surfaces, on which a transmission line is formed;
a transmitting terminal formed on one of the pair of mount surfaces; and
a first receiving circuit mounted on the one of the pair of mount surfaces, and receiving a signal transmitted from the transmitting terminal through the transmission line formed on the printed wiring board, wherein
the transmission line comprises:
a main wiring configured to transmit the signal from the transmitting circuit;
a first branching wiring branched from a first branching point of the main wiring, and connected to the first receiving circuit;
a second branching wiring branched from the first branching point, and connected to the second receiving circuit through a land formed on the other of the pair of mount surfaces; and
an open stub having one end connected to the land.

14. A printed wiring board comprising:
a first mount surface on which a transmitting circuit and a first receiving circuit are formed;
a second mount surface on which a second receiving circuit is formed, and which opposes the first mount surface;
a transmission line formed in at least one of the first and second mount surfaces and n inner layer, wherein
the transmission line comprises:
a main wiring configured to transmit a signal from the transmitting circuit;
a first branching wiring branched from a first branching point of the main wiring, and connected to the first receiving circuit through a land formed on the one of the pair of mount surfaces;
a second branching wiring branched from the first branching point, and connected to the second receiving circuit through a land formed on the other of the pair of mount surfaces; and
an open stub having one end connected to the land formed on the one or the other of the pair of mount surfaces.

15. The printed wiring board according to claim 14, wherein
the main wiring is formed on the one of the pair of mount surfaces, and
the second branching wiring has a via penetrating between the one and the other of the pair of mount surfaces provided at the first branching point and has a wiring pattern formed on the other of the pair of mount surfaces.

16. The printed wiring board according to claim 14, wherein
the main wiring is formed in an inner layer inside of the printed wiring board,
the first branching wiring has an area, from the first branching point to the one of the pair of the mount surfaces, of a via penetrating between the one and the other of the pair of mount surfaces provided at the first branching point, and has a wiring pattern formed on the other of the pair of mount surfaces,
the second branching wiring has an area, of the via, from the first branching point to the other of the pair of the mount surfaces, and has a wiring pattern formed on the other of the pair of mount surfaces.

17. The printed wiring board according to claim 14, wherein
a second branching point of the main wiring is provided at a side of the first branching point opposite to the transmitting circuit,
a third branching wiring is branched from the second branching point and is connected to a third receiving circuit, and
a fourth branching wiring is branched from the second branching point and is connected to a fourth receiving circuit.

18. The printed wiring board according to claim 14, wherein
the open stub has an electrical length set within a range −10% to +30% of an electrical length of an effective inner wiring including a capacitive component of the first receiving circuit.
